(19) United States
(12) Patent Application Publication
(10) Pub. No.: US 2023/0358534 A1
(43) Pub. Date: Nov. 9, 2023

(54) PHOTODETECTOR AND DISTANCE MEASURING SYSTEM

(71) Applicant: Panasonic Intellectual Property Management Co., Ltd., Osaka (JP)

(72) Inventor: Akito INOUE, OSAKA FU (JP)

(21) Appl. No.: 18/345,811

(22) Filed: Jun. 30, 2023

Related U.S. Application Data
(63) Continuation of application No. PCT/JP2022/011415, filed on Mar. 14, 2022.

(30) Foreign Application Priority Data
Mar. 22, 2021 (JP) 2021-047622

(51) Int. Cl. G01C 3/06; G01S 17/894; G01S 7/4863; H04N 25/773

(52) U.S. Cl. CPC G01C 3/06; G01S 17/894; G01S 7/4863; H04N 25/773

(57) ABSTRACT

A photodetector includes a plurality of pixel circuits. Each of the pixel circuits includes an SPAD and a first element being a variable resistor or a switch. The first element has an end in one direction connected to one end of the SPAD. Ends of the first elements in another direction are connected together in parallel. The other ends of the SPADs are connected together in parallel. The other ends connected together in parallel are connected to a second resistor. A resistance value R₂ of the second resistor is higher than a resistance value R₁ of a resistive component at the end of each of the first elements in the another direction.

### CROSS-REFERENCE TO RELATED APPLICATION

This is a continuation of International Application No. PCT/JP2022/011415 filed on Mar. 14, 2022, which claims priority to Japanese Patent Application No. 2021-047622 filed on Mar. 22, 2021. The entire disclosures of these applications are incorporated by reference herein.

### BACKGROUND

The present disclosure relates to a photodetector and a distance measuring system.

In recent years, high-sensitivity photodetectors have been used in various fields such as medical care, communications, biology, chemistry, monitoring, in-vehicle use, and radiation detection. An avalanche photodiode (hereinafter also referred to as “APD”) is used as one of means for increasing the sensitivity. The APD is a photodiode that increases the photodetection sensitivity by using avalanche breakdown to multiply signal charges generated by photoelectric conversion.

A photodetection apparatus and a solid state image sensor each including an APD are disclosed in Japanese Patent No. 5927334 and Japanese Patent Application No. 2018-159472, respectively.

### SUMMARY

In Japanese Patent No. 5927334, a plurality of APDs are connected together in parallel, and a reverse bias voltage that is higher than the breakdown voltage is applied between the anode and cathode of each of the APDs. The APDs are each connected in series to a quenching resistor. This quenching resistor stops avalanche multiplication.

If a photodetector as described in Japanese Patent No. 5927334 is used for the purpose of detecting emitted light, e.g., for a time of flight (TOF) method, background light with higher intensity than the emitted light causes false detection.

In Japanese Patent Application No. 2018-159472, a switch or a transistor is connected in series to each of a plurality of APDs. In Japanese Patent Application No. 2018-159472, these switches or transistors are turned on during a reset period, and turned off during a light exposure period, thereby reducing false detection caused by the background light.

However, the configuration of Japanese Patent Application No. 2018-159472 may increase the dark count due to shoot-through current flowing through the APDs during the reset period.

An object of the present disclosure is to provide a photodetector that limits the dark count while reducing false detection caused by background light.

To solve the problem, a photodetector according to one embodiment of the present disclosure includes: a plurality of pixels. Each of the pixels includes: a single photon avalanche diode (SPAD); and a first element being a variable resistor or a switch. The first element has an end in one direction connected to one end of the SPAD. Ends of the first elements in another direction are connected together in parallel. Other ends of the SPADs are connected together in parallel. The other ends connected together in parallel are connected to a second resistor. A resistance value of the second resistor is higher than a resistance value of a resistive component at the end of each of the first elements in the another direction.

According to the present disclosure, the dark count can be limited while false detection caused by background light is reduced.

### BRIEF DESCRIPTION OF THE DRAWINGS

FIG. 1 illustrates an example of a circuit configuration of a photodetector according to a first embodiment.

FIGS. 2A-2D are intended to compare experimental results between the photodetector 1 according to the first embodiment and a known photodetector.

FIG. 3 is a graph showing the relation between the amplitude of a voltage applied to a single photon avalanche diode (SPAD) and the voltage difference between a first power supply and a second power supply according to the first embodiment.

FIG. 4 is a block diagram showing an example of a photodetector according to a second embodiment.

FIG. 5 is a timing diagram of a pixel circuit according to the second embodiment.

FIG. 6 is a block diagram showing an example of a photodetector according to a third embodiment.

FIG. 7 is a timing diagram of a pixel circuit according to the third embodiment.

FIG. 8 is a block diagram showing an example of a photodetector according to a fourth embodiment.

FIG. 9 is a timing diagram of a pixel circuit according to the fourth embodiment.

FIG. 10 shows simulation results of the photodetector according to the fourth embodiment.

FIG. 11 is a plan view illustrating an example of a device structure of the photodetector shown in FIG. 8.

FIG. 12 is a cross-sectional view illustrating the example of the device structure of the photodetector shown in FIG. 8.

FIG. 13 is a plan view illustrating the example of the device structure of the photodetector shown in FIG. 8.

FIG. 14 is a cross-sectional view illustrating the example of the device structure of the photodetector shown in FIG. 8.

FIG. 15 is a cross-sectional view illustrating another example of the device structure of the photodetector shown in FIG. 8.

FIG. 16 is a cross-sectional view illustrating still another example of the device structure of the photodetector shown in FIG. 8.

FIG. 17 is a cross-sectional view illustrating yet another example of the device structure of the photodetector shown in FIG. 8.

FIG. 18 is a block diagram illustrating a distance measuring system according to a fifth embodiment.

### DETAILED DESCRIPTION

Embodiments of the present invention will be described in detail with reference to the drawings. The following description of advantageous embodiments is only examples in nature, and is not intended to limit the scope, applications or use of the present disclosure.

In the following description, “one end” of a transistor refers to either one of a source and a drain of the transistor, and “the other end” of the transistor refers to the other one of the source and the drain of the transistor.

### First Embodiment

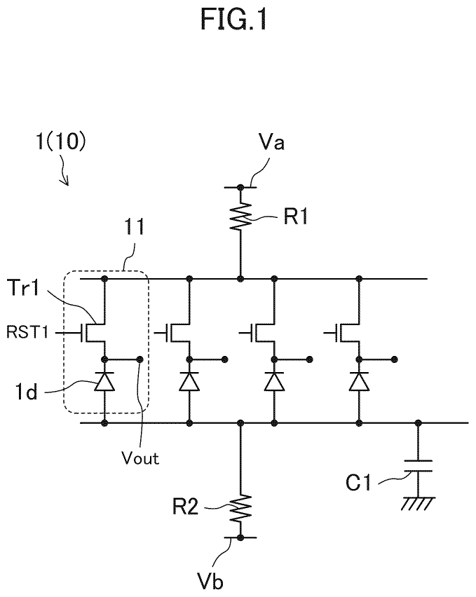

FIG. 1 illustrates an example of a circuit configuration of a photodetector according to a first embodiment. A photodetector 1 according to this embodiment includes a pixel array circuit 10. As will be described in detail later, the photodetector 1 includes a pixel array 200 that includes a plurality of pixels 101 arranged in an array on a semiconductor chip 151. The pixel array 200 includes the pixel array circuit 10, and each of pixels 101 includes a pixel circuit 11 to be described later.

The pixel array circuit 10 includes a first resistor R1 (a resistive component), a second resistor R2, a first capacitor C1, and a plurality of pixel circuits 11. One end of the first resistor R1 is connected to a first power supply Va. One end of the second resistor R2 is connected to a second power supply Vb. One end of the first capacitor C1 is connected to a ground power supply.

Each of the pixel circuits 11 includes a single photon avalanche diode (SPAD) 1d and a first transistor Tr1 (a first element, a first reset transistor). The SPAD is an electronic element that delivers one electrical pulse signal with large amplitude by avalanche multiplication upon incidence of one light particle (photon) thereon.

Specifically, the drain (an end in another direction) of the first transistor Tr1 is connected to the drains of the first transistors Tr1 of the other pixel circuits 11 and the other end of the first resistor R1, the source (an end in one direction) thereof is connected to the cathode of the SPAD 1d, and the gate thereof receives a first reset signal RST1. The SPAD 1d has an anode connected to the anodes of the other SPADs 1d, the other end of the second resistor R2, and the first capacitor C1. In other words, the drains of the first transistors Tr1 of the pixel circuits 11 are connected together in parallel, and are connected to the other end of the first resistor R1. The anodes of the SPADs 1d of the pixel circuits 11 are connected together in parallel, and are connected to the other end of the second resistor R2 and the other end of the first capacitor C1.

In each of the pixel circuits 11, a node is provided between the source of the first transistor Tr1 and the cathode of the SPAD 1d to deliver an output signal Vout of the pixel circuit 11.

In FIG. 1, the first transistor Tr1 is an n-type transistor, but may be a p-type transistor, a variable resistor, a switch, or any other component.

In the photodetector 1, the voltage of the SPAD 1d is reset during a reset period, the SPAD 1d is exposed to light during a light exposure period subsequent to the reset period, and a signal indicating the result of the light exposure (the output signal Vout) is delivered (read) from the pixel circuit 11 during a reading period subsequent to the light exposure period. The first transistor Tr1 of each of the pixel circuits 11 receives the first reset signal RST1 at high level during the reset period so as to be turned on (so as to be brought into conduction), and receives the first reset signal RST1 at low level during the light exposure period so as to be turned off (so as not to be brought into conduction).

Forming a pixel array circuit 10 similar to that shown in FIG. 1 in the photodetector 1 allows voltage fluctuation during a period except the light exposure period to be reset during the reset period. This can reduce false detection caused by background light. The second resistor R2 having a resistance value R₂ that is higher than the resistance value R₁ of the first resistor R1 can allow mainly the second resistor R2 to experience a voltage drop due to the shoot-through current flowing through the SPAD 1d during the reset period. This can reduce the voltage drop across the first resistor R1 and the first transistor Tr1. This can limit the dark count as will be described later.

In particular, the second resistor R2 quenching the shoot-through current during resetting can further provide the advantages described above.

Here, the condition on which the second resistor R2 quenches the shoot-through current during resetting is expressed by the following formula (1).

$$\begin{matrix}[ Formula 1 ] & \\ {R}_{2} ≧ \frac{Δ V}{{NI}_{pix}} & ( 1 )\end{matrix}$$

Note that ΔV represents the voltage change of the first capacitor C1 required for quenching, Iₚᵢₓ represents the current value of the shoot-through current through one pixel circuit 11, and N represents the number of the pixel circuits 11 (the pixels 101) through which the shoot-through current flows. Here, ΔV is approximately equal to an excess bias, and Iₚᵢₓ is approximately equal to the on-state current of the first transistor Tr1. Here, the excess bias is a reverse bias applied to the SPAD 1d (i.e., a value obtained by subtracting the breakdown voltage of the SPAD 1d from the difference between the voltage values of the first and second power supplies Va and Vb), and has the same definition as its general definition.

Here, R₂≥100Ω, where ΔV=1 V, Iₚᵢₓ=1 μA, and N=10⁴. However, the value depends on the area of the SPAD 1d and W (gate width)/L (gate length) of the first transistor Tr1, and the number N depends on the number of the pixel circuits 11 (pixels 101), the dark count rate (DCR), and the light intensity of background light. In particular, if the number of the pixel circuits 11 is great, the resistance value R₂ can be low.

The first resistor R1 does not have to be mounted on a semiconductor substrate including the pixel array circuit 10, and may be an interconnect resistance or a parasitic component in the pixel array circuit 10. The first resistor R1 may include a parallel resistance obtained by connecting the diffusive resistance, the contact resistance, the interconnect resistance, and the channel resistance between the source and drain of the first transistor Tr1 together in parallel. In this case, the resistance value R₁ of the first resistor R1 decreases as the number of the pixels 101 increases. Thus, in one preferred embodiment, the number of the pixels 101 is greater. The resistance value R₁ of the first resistor R1 is typically less than 100Ω and may be 0Ω.

Thus, to achieve the second resistor R2 having a resistance value R₂ that is higher than the resistance value R₁ of the first resistor R1, the resistance value R₂ of the second resistor R2 is higher than or equal to 100Ω in one preferred embodiment.

In addition, the above-described formula (1) shows that the value of the second resistor R2 required for quenching changes according to the number of the pixel circuits 11, and that the required value of the second resistor R2 decreases as the number of the pixel circuits 11 increases. Thus, in one preferred embodiment, the number of the pixel circuits 11 is greater. If the resistance value of the second resistor is set to be higher than the resistance value of the first resistor (i.e., to be 100Ω), the number of the pixel circuits 11 (pixels 101) is, in one preferred embodiment, greater than or equal to 10⁴ under typical conditions such as ΔV=1 V and Iₚᵢₓ=1 μA. Examples of the second resistor R2 include a diffusive resistance of the semiconductor substrate, a resistance mounted on the semiconductor substrate, a resistance in the associated circuit, and an external resistance. Examples of the first capacitor C1 include a junction capacitance, a capacitance associated with the mounting of a semiconductor chip, a capacitance resulting from a circuit on a mounting board, and an external capacitance.

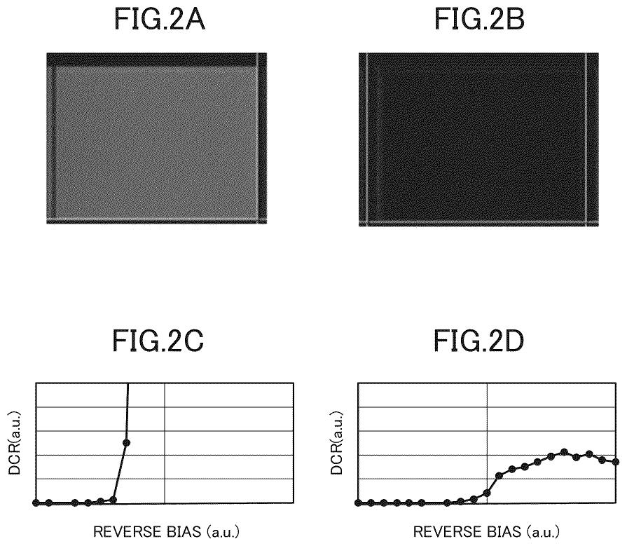

FIGS. 2A-D are intended to compare experimental results between the photodetector 1 according to the first embodiment and a known photodetector. The known photodetector in FIGS. 2A-D is the photodetector described in Japanese Patent Application No. 2018-159472, and includes a second resistor R2 with a value that is lower than the value of the first resistor R1 of the photodetector 1 according to this embodiment. FIGS. 2A-D show the results of the photodetector 1 and the known photodetector each including 1200×900 pixels (pixel circuits 11). The resistance value R₂ of the second resistor R2 of the photodetector 1 is 1 kΩ, and the resistance value R₂ of the second resistor R2 of the known photodetector is 10Ω.

FIG. 2A illustrates an image in the form of which the difference between the output signal Vout of the known photodetector after the light exposure period and a reference voltage under the dark conditions has been delivered. FIG. 2B illustrates an image in the form of which the difference between the output signal Vout of the photodetector 1 after the light exposure period and the reference voltage under the dark conditions has been delivered. Here, the reference voltage is the value of the output signal Vout immediately after the resetting. A lighter one of these images illustrated indicates a larger difference between the output signal Vout immediately after the light exposure period and the reference voltage, and a darker one of these images indicates a smaller difference therebetween. FIGS. 2A and 2B show that FIG. 2A is lighter than FIG. 2B, and that the voltage value of the output signal Vout of each of many of the pixels after the light exposure period under the dark conditions fluctuates from the reference voltage. As such, in the known photodetector, the resistance value R₂ of the second resistor R2 is lower than the resistance value R₁ of the first resistor R1. Thus, the voltage value of the output signal Vout after the light exposure period under the dark conditions fluctuates from the reference voltage. This fluctuation in the voltage value triggers the dark count, which is responsible for deterioration in image quality. In contrast, in the photodetector 1 of the present invention, the resistance value R₂ of the second resistor R2 is higher than the resistance value R1 of the first resistor R1. This reduces fluctuation in the output signal Vout during the reset period, and lowers the dark count. This shows that the configuration shown in FIG. 1 reduces the DCR.

FIG. 2C is a graph showing variation in the DCR of the known photodetector. FIG. 2D is a graph showing variation in the DCR of the photodetector 1. FIGS. 2C and 2D show that the configuration shown in FIG. 1 reduces the DCR.

In FIG. 1, the source of the first transistor Tr1 is connected to the cathode of the SPAD 1d, but may be connected to the anode of the SPAD 1d.

Here, the conductivity type of the first transistor Tr1 may be set to be the same as the conductivity type of one end (the cathode in FIG. 1) of the SPAD 1d connected to the first transistor Tr1. In this case, as the voltage difference between the first and second power supplies Va and Vb increases, the shoot-through current flowing through the first transistor Tr1 increases. As a result, the IR drop across the second resistor R2 increases. This can reduce variation in the reverse bias applied to the SPAD 1d even if the voltage difference (reverse bias) between the first and second power supplies Va and Vb is increased.

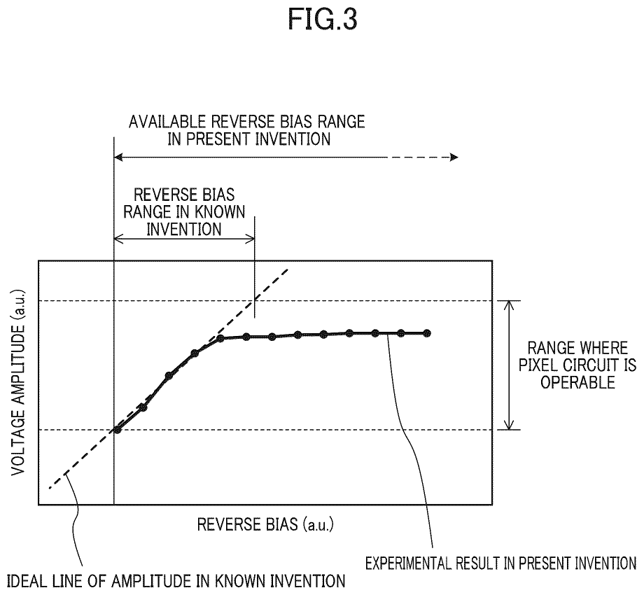

FIG. 3 is a graph showing the relation between the amplitude of the voltage applied to the SPAD and the voltage difference between the first and second power supplies in a situation where the conductivity type of the first transistor Tr1 is identical to that of the one end (the cathode in FIG. 1) of the SPAD 1d connected to the first transistor Tr1, in the first embodiment. In FIG. 3, the horizontal axis represents the voltage difference (reverse bias) between the first and second power supplies Va and Vb, and the vertical axis represents the voltage amplitude of the output signal Vout from the reference voltage after the light exposure period. The experimental results of the photodetector 1 are plotted by the solid line, and theoretical values of the known photodetector are plotted by the dashed line. The theoretical values of the known photodetector in FIG. 3 are, for example, theoretical values of the SPAD described in Japanese Patent No. 5927334 or Japanese Patent Application No. 2018-159472, i.e., theoretical values of a general SPAD.

As shown in FIG. 3, in the known photodetector, the reverse bias is proportional to the voltage amplitude of the SPAD 1d. Thus, the range of the reverse bias had to be narrowed to operate the photodetector within the range where the pixel circuit is operable. In particular, the upper limit of an available range of the reverse bias has a difference of about one volt from the lower limit thereof. In contrast, even if the reverse bias is a higher voltage that is higher than or equal to the breakdown voltage, the voltage amplitude of the SPAD 1d of the photodetector 1 falls within the range where the pixel circuit is operable. Thus, the reverse bias can be set to be in a wider range including the breakdown voltage and higher voltages.

In general, the breakdown voltage has a dependence on temperature and a chip-to-chip difference, and the available range of the reverse bias fluctuates with fluctuation in the breakdown voltage. Thus, it is requisite to set the voltage values of the first and second power supplies Va and Vb according to the fluctuation in the available range of the reverse bias. For example, in Japanese Patent No. 5211095, a circuit that changes the bias conditions in accordance with temperature fluctuations is provided, thereby reducing fluctuations in the output and characteristics of the breakdown voltage resulting from the temperature fluctuations. This configuration, however, increases the circuit scale and the system scale. In contrast, the available range of the reverse bias of the photodetector 1 according to this embodiment is wide. This enables setting of the values Va and Vb satisfying the available range of the reverse bias for each of guaranteed operating temperatures, and leads to elimination of the configuration in which the set bias is changed according to the temperature change as described in Japanese Patent No. 5211095.

Specifically, in general, the breakdown voltage is high at high temperature and is low at low temperature. The upper limit of the available range of the reverse bias of the photodetector 1 according to this embodiment can be set to be greater. Thus, a reverse bias higher than or equal to the breakdown voltage at the highest one of guaranteed operating temperatures may be applied to the SPAD 1d.

### Second Embodiment

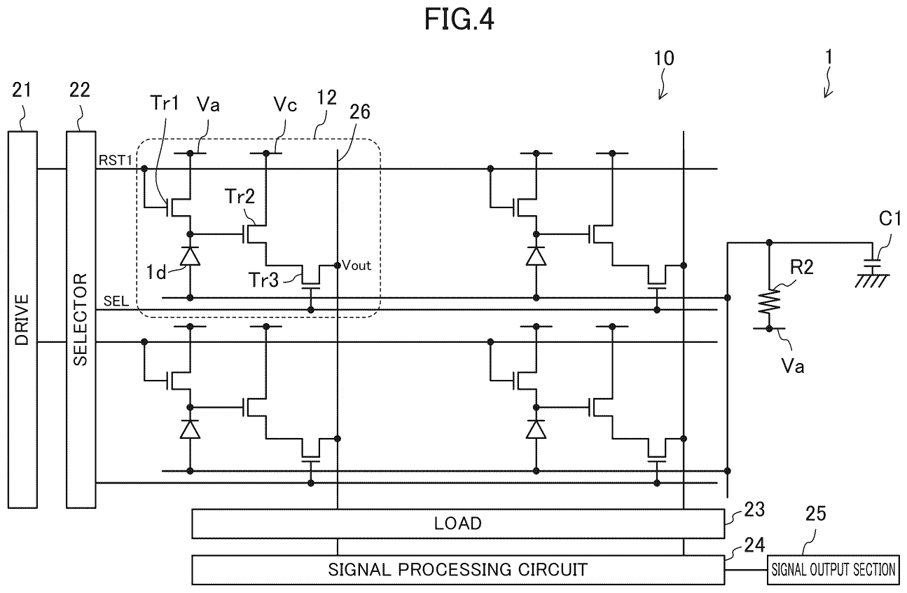

FIG. 4 is a block diagram showing an example of a photodetector according to a second embodiment. In FIG. 4, the photodetector 1 includes a drive 21, a selector 22, a load 23, a signal processing circuit 24, and a signal output section 25 in addition to the components shown in FIG. 1.

A pixel array circuit 10 includes a plurality of pixel circuits 12. Each of the pixel circuits 12 includes a second transistor Tr2 (source follower transistor) and a third transistor Tr3 (selection transistor) in addition to the components of the pixel circuit 11 shown in FIG. 1. One end of the second transistor Tr2 is connected to a third power supply Vc, the other end thereof is connected to one end of the third transistor Tr3, and the gate thereof is connected to the drain of the first transistor Tr1 and the cathode of the SPAD 1d. The gate of the third transistor Tr3 receives a selection signal SEL, and the other end thereof is connected to a signal output line 26. The third transistor Tr3 delivers an output signal Vout to the signal output line 26 in accordance with the received selection signal SEL.

The drive 21 delivers a first reset signal RST1 to the gates of the first transistors Tr1 of the pixel circuits 12 to drive the first transistors Tr1. The selector 22 delivers the selection signal SEL to the gates of the third transistors Tr3 to drive the third transistors Tr3. The signal processing circuit 24 is connected to the signal output lines 26 via the load 23 to receive the input of the output signal Vout delivered from each pixel circuit 12. The signal processing circuit 24 performs a predetermined process on the received output signal Vout, and delivers a signal to the signal output section 25. The signal output section 25 generates the detection result of the photodetector 1 in the form of numerical data, image data, or any other type of data, based on the signal received from the signal processing circuit 24.

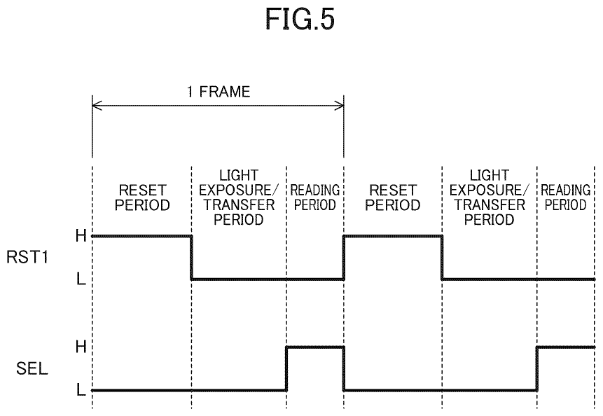

FIG. 5 is a timing diagram of a pixel circuit according to the second embodiment. In the following description, “H” indicates that a signal is at high level, and “L” indicates that a signal is at low level. FIG. 5 shows operation of one pixel circuit 12.

In FIG. 5, one frame includes a reset period, a light exposure period, and a reading period. The pixel circuit 12 repeatedly performs operations in one frame.

During the reset period, the first reset signal RST1 is at high level, and the selection signal SEL is at low level. Thus, the first transistor Tr1 is turned on, and the third transistor Tr3 is turned off. This allows the voltage of the SPAD 1d to be reset to the voltage value of the first power supply Va during the reset period.

During the light exposure period, the first reset signal RST1 and the selection signal SEL are at low level. Thus, the first and third transistors Tr1 and Tr3 are turned off. This allows the SPAD 1d having received incident light to generate signal charges (to be exposed to light) by avalanche multiplication during the light exposure period. As a result, the cathode voltage of the SPAD 1d changes.

During the reading period, the first reset signal RST1 is at low level, and the selection signal SEL is at high level. Thus, the first transistor Tr1 is turned off, and the third transistor Tr3 is turned on. Thus, during the reading period, the output signal Vout indicating the result of exposing the SPAD 1d to light is delivered to the signal output line 26.

In FIG. 5, the light exposure period and the reading period are separately provided. However, the light exposure period may be omitted so that only the reading period is provided, and while light exposure is performed, the result of the light exposure may be read from the pixel circuit 12.

### Third Embodiment

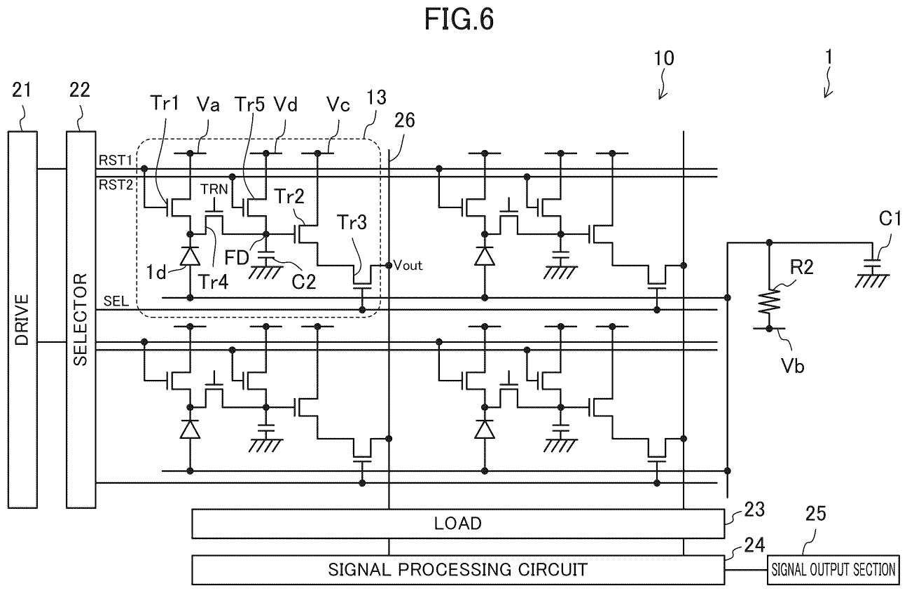

FIG. 6 is a block diagram showing an example of a photodetector according to a third embodiment. In the pixel array circuit 10 shown in FIG. 6, each of pixel circuits 13 includes a fourth transistor Tr4 (transfer transistor), a fifth transistor Tr5 (second reset transistor), and a second capacitor C2 in addition to the components of the pixel circuit 12 shown in FIG. 4.

One end of the fourth transistor Tr4 is connected to the drain of a first transistor Tr1 and the cathode of an SPAD 1d, the gate thereof receives a transfer signal TRN, and the other end thereof is connected to a floating diffusion FD (in some cases, hereinafter simply referred to as the “FD”). The fourth transistor Tr4 transfers signal charges delivered from the SPAD 1d to the FD in response to the transfer signal TRN.

One end of the fifth transistor Tr5 is connected to a fourth power supply Vd, the other end thereof is connected to the FD, and the gate thereof receives a second reset signal RST2. One end of the second capacitor C2 is connected to the FD, and the other end thereof is connected to a ground power supply.

In FIG. 6, the gate of the second transistor Tr2 is connected to the FD. Specifically, the signal charges delivered from the SPAD 1d are transferred to the FD by the fourth transistor Tr4, and are fed to the gate of the second transistor Tr2. That is, the second transistor Tr2 functions as a part of a source follower circuit that reads the voltage of the FD.

The second capacitor C2 is a diffusion stray capacitance, and includes a pn junction capacitance and an interconnect capacitance.

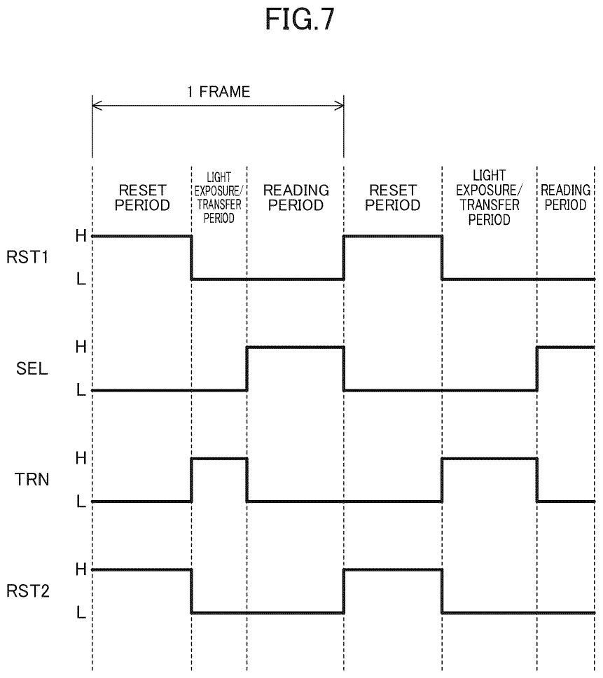

FIG. 7 is a timing diagram of a pixel circuit according to the third embodiment. FIG. 7 shows operation of one pixel circuit 13 just like FIG. 5.

In FIG. 7, one frame includes a reset period, a light exposure/transfer period, and a reading period. The pixel circuit 13 repeatedly performs operations in one frame.

During the reset period, a first reset signal RST1 and the second reset signal RST2 are at high level, a selection signal SEL is at low level, and a transfer signal TRN is at low level. Thus, the first and fifth transistors Tr1 and Tr5 are turned on, the third transistor Tr3 is turned off, and the fourth transistor Tr4 is turned off. This allows the voltage of the SPAD 1d to be reset to the voltage value of the first power supply Va, and allows the voltage of the FD to be reset to the voltage value of the fourth power supply Vd, during the reset period. During the reset period, the SPAD 1d and the FD are reset at the same time. However, the reset period may separately include a period during which the SPAD 1d is reset and a period during which the FD is reset.

During the light exposure/transfer period, the first and second reset signals RST1 and RST2 are at low level, the selection signal SEL is at low level, and the transfer signal TRN is at high level. Thus, the first and fifth transistors Tr1 and Tr5 are turned off, the third transistor Tr3 is turned off, and the fourth transistor Tr4 is turned on. This allows the SPAD 1d having received incident light to generate signal charges (to be exposed to light) by avalanche multiplication during the light exposure/transfer period. As a result, the cathode voltage of the SPAD 1d changes. The signal charges generated by the SPAD 1d are transferred to the second capacitor C2 via the fourth transistor Tr4 and the FD, resulting in a change in the voltage of the second capacitor C2. During the light exposure/transfer period, exposure of the SPAD 1d to light and the transfer of the signal charges to the FD are performed at the same time. However, the light exposure/transfer period may separately include a period during which the SPAD 1d is exposed to light and a period during which the signal charges are transferred.

During the reading period, the first and second reset signals RST1 and RST2 are at low level, the selection signal SEL is at high level, and the transfer signal TRN is at low level. Thus, the first and fifth transistors Tr1 and Tr5 are turned off, the third transistor Tr3 is turned on, and the fourth transistor Tr4 is turned off. Thus, during the reading period, the signal charges stored in the second capacitor C2 are delivered to (read by) the signal processing circuit 24 via a signal output line 26 and a load 23. That is, the output signal Vout is delivered. In FIG. 6, the fourth transistor Tr4 is turned off during the reading period, unlike in FIG. 4. Thus, even if the SPAD 1d receives incident light during the reading period, the signal charges are not transferred from the SPAD 1d to the second capacitor C2, and the output signal Vout is not delivered to the signal processing circuit 24. This allows the light exposure period to be set to be shorter.

### Fourth Embodiment

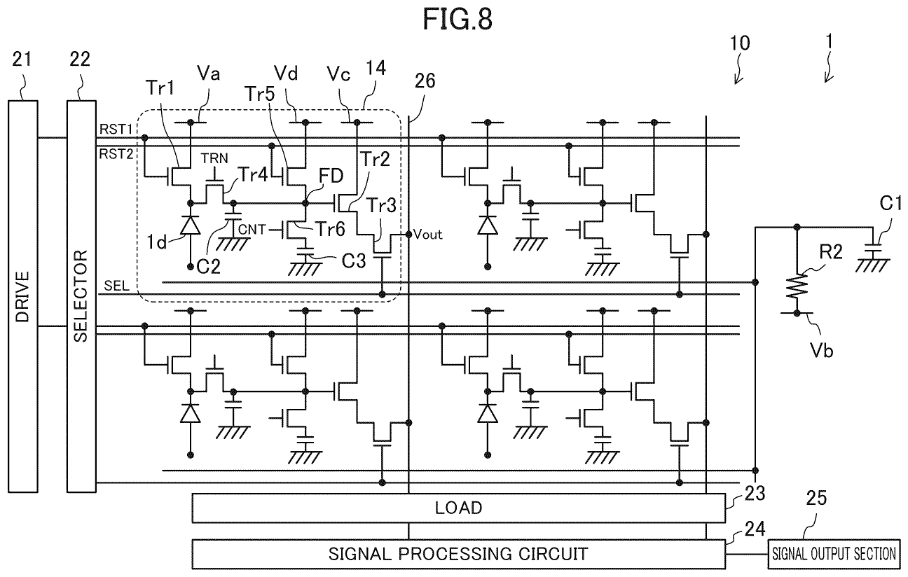

FIG. 8 is a block diagram showing an example of a photodetector according to a fourth embodiment. In the pixel array circuit 10 shown in FIG. 8, each of pixel circuits 14 includes a sixth transistor Tr6 (storage transistor) and a third capacitor C3 (storage capacitor) in addition to the components of the pixel circuit 13 shown in FIG. 6.

One end (a first end) of the sixth transistor Tr6 is connected to the FD, the gate thereof receives a count signal CNT, and the other end (a second end) thereof is connected to one end of the third capacitor C3. The other end of the third capacitor C3 is connected to a ground power supply. The sixth transistor Tr6 makes the third capacitor C3 store the signal charges transferred to the FD in response to the count signal CNT. The third capacitor C3 may have a higher capacitance than the second capacitor C2 does.

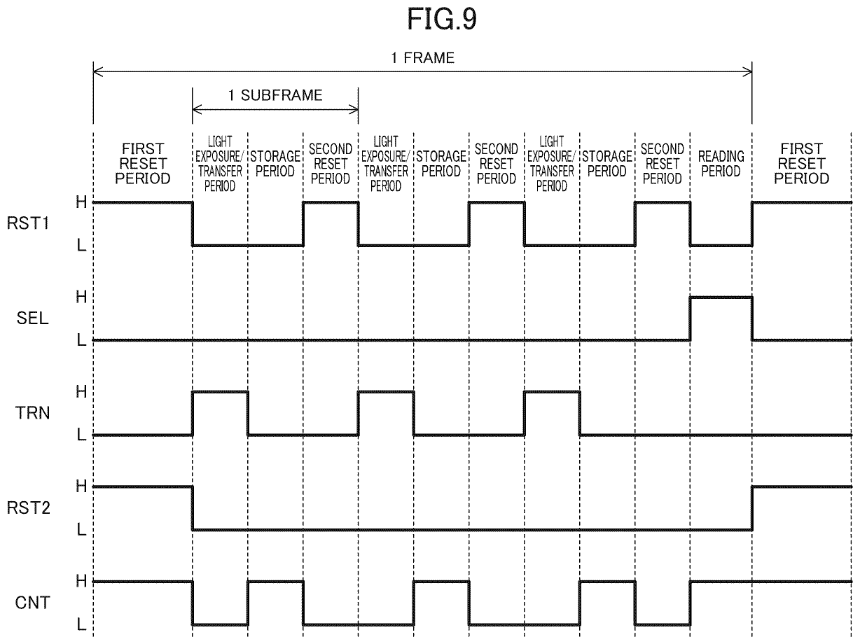

FIG. 9 is a timing diagram of a pixel circuit according to the fourth embodiment. FIG. 9 shows operation of one pixel circuit 14 just like FIG. 7.

In FIG. 9, one frame includes a first reset period, a plurality of (three in FIG. 9) subframes, and a reading period. Each of the subframes includes a light exposure/transfer period, a storage period, and a second reset period. The pixel circuit 14 repeatedly performs operations in one frame. Note that one frame may include two or more subframes.

During the first reset period, a first reset signal RST1 is at high level, a selection signal SEL is at low level, a transfer signal TRN is at low level, a second reset signal RST2 is at low level, and the count signal CNT is at high level. Thus, a first transistor Tr1 is turned on, a third transistor Tr3 is turned off, a fourth transistor Tr4 is turned off, a fifth transistor Tr5 is turned on, and the sixth transistor Tr6 is turned on. This allows the voltage of the SPAD 1d to be reset to the voltage value of the first power supply Va, and allows the voltage values of the FD and the third capacitor C3 to be reset to the voltage value of the fourth power supply Vd, during the reset period. During the reset period, the SPAD 1d, the FD, and the third capacitor C3 are reset at the same time. However, the reset period may separately include a period during which the SPAD 1d is reset, a period during which the FD is reset, and a period during which the third capacitor C3 is reset.

During the light exposure/transfer period, the first reset signal RST1 is at low level, the selection signal SEL is at low level, the transfer signal TRN is at high level, the second reset signal RST2 is at low level, and the count signal CNT is at low level. Thus, the first transistor Tr1 is turned off, the third transistor Tr3 is turned off, the fourth transistor Tr4 is turned on, the fifth transistor Tr5 is turned off, and the sixth transistor Tr6 is turned off. This allows the SPAD 1d having received incident light to generate signal charges (to be exposed to light) by avalanche multiplication during the light exposure/transfer period. As a result, the cathode voltage of the SPAD 1d changes. The signal charges generated by the SPAD 1d are transferred to the second capacitor C2 via the fourth transistor Tr4 and the FD, resulting in a change in the voltage value of the second capacitor C2. During the light exposure/transfer period, exposure of the SPAD 1d to light and the transfer of the signal charges to the FD are performed at the same time. However, the light exposure/transfer period may separately include a period during which the SPAD 1d is exposed to light and a period during which the signal charges are transferred.

During the storage period, the first reset signal RST1 is at low level, the selection signal SEL is at low level, the transfer signal TRN is at low level, the second reset signal RST2 is at low level, and the count signal CNT is at high level. Thus, the first transistor Tr1 is turned off, the third transistor Tr3 is turned off, the fourth transistor Tr4 is turned off, the fifth transistor Tr5 is turned off, and the sixth transistor Tr6 is turned on. Thus, during the storage period, the signal charges stored in the second capacitor C2 are transferred to the third capacitor C3 via the FD and the sixth transistor Tr6, and are stored in the third capacitor C3.

During the second reset period, the first reset signal RST1 is at high level, the selection signal SEL is at low level, the transfer signal TRN is at low level, the second reset signal RST2 is at low level, and the count signal CNT is at low level. Thus, the first transistor Tr1 is turned on, the third transistor Tr3 is turned off, the fourth transistor Tr4 is turned off, the fifth transistor Tr5 is turned off, and the sixth transistor Tr6 is turned off. This allows the voltage of the SPAD 1d to be reset to the voltage value of the first power supply Va during the second reset period. Thus, the SPAD 1d can be exposed to light during the subsequent light exposure period. During the second reset period, the count signal CNT may be at low level, and the sixth transistor Tr6 may be turned on.

During the reading period, the first reset signal RST1 is at low level, the selection signal SEL is at high level, the transfer signal TRN is at low level, the second reset signal RST2 is at low level, and the count signal CNT is at high level. Thus, the first transistor Tr1 is turned off, the third transistor Tr3 is turned on, the fourth transistor Tr4 is turned off, the fifth transistor Tr5 is turned off, and the sixth transistor Tr6 is turned on. Thus, during the reading period, the signal charges stored in the third capacitor C3 are delivered to (read by) a signal processing circuit 24 via a signal output line 26 and a load 23.

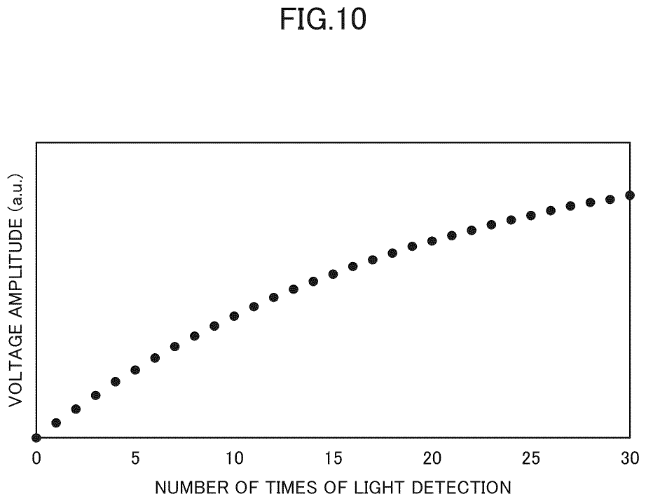

FIG. 10 shows simulation results of the photodetector according to the fourth embodiment. In FIG. 10, the vertical axis represents the voltage amplitude of the output signal Vout, and the horizontal axis represents the number of times one SPAD 1d detects light.

In the photodetector 1 shown in FIG. 8, the pixel circuits 14 deliver output signals Vout with different voltage amplitudes in response to the light detection results of the associated SPADs 1d. As shown in FIG. 10, the number of times the SPAD 1d detects light within each of the subframes can be determined in accordance with the voltage amplitude of the associated output signal Vout. Determining the number of times each pixel circuit 14 detects light based on the voltage amplitude of the output signal Vout enables determination of the number of photons incident on the SPAD 1d of the pixel circuit 14. In general, the time required to transfer charges or to store charges within the pixel circuit 14 is much shorter than the time required to process a signal or to deliver a signal. The time required to process a signal or to deliver a signal is about 1 ms for, e.g., one million pixels. In contrast, it takes a time of 10 ns to 1 ns to transfer/store charges within each pixel. Thus, the speed at which the charges are transferred/stored within the pixel is 100,000 times or more as high as the speed at which a signal is processed or any other similar speed. Thus, the photodetector according to this embodiment can substantially prevent a delay caused by signal processing and signal output, and can improve the effective frame rate.

(Device Structure of Photodetector)

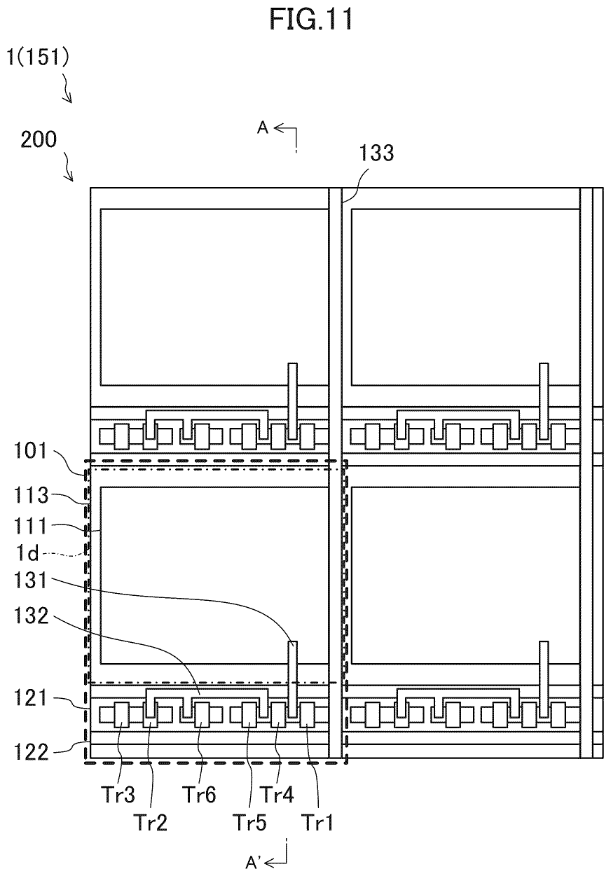

FIG. 11 is a plan view illustrating an example of a device structure of the photodetector shown in FIG. 8. In FIG. 11, interconnects except first to third interconnects 131 to 133, a lens 142, and other components are omitted for convenience.

As illustrated in FIG. 11, a pixel array 200 including a plurality of (2×2 in FIG. 11) pixels 101 is mounted on a semiconductor chip 151. Each of the pixels 101 includes the pixel circuit 14 shown in FIG. 8, and the pixel array 200 includes the pixel array circuit 10 shown in FIG. 8.

Specifically, the SPAD 1d is arranged in an upper portion of each pixel 101 in the drawing, and the first to sixth transistors Tr1 to Tr6 are arranged side by side in the lateral direction of the drawing in a lower portion of the pixel 101 in the drawing.

An interconnect layer on a first principal surface S1 of a semiconductor substrate includes the first interconnect 131, the second interconnect 132, and the third interconnect 133. The first interconnect 131 connects the SPAD 1d and the first transistor Tr1 together. The second interconnect 132 connects the gate of the second transistor Tr2, the source of the sixth transistor Tr6, and the drain of the fourth transistor Tr4 together. The third interconnect 133 connects the drain of the first transistor Tr1 and the first power supply Va together.

Here, the third interconnect 133 is thicker than the other interconnects, and has a lower contact resistance and a lower interconnect resistance. The drains of the first transistors Tr1 of the pixels 101 are connected together through the associated third interconnect 133. This can limit the resistance value of the first resistor R1 to a low level. In FIG. 11, the drains of the first transistors Tr1 are connected together through the associated third interconnect 133 extending in the longitudinal direction of the drawing, but may be connected together through the associated third interconnect 133 extending in the lateral direction, or may be connected together through the third interconnect 133 in the shape of a lattice.

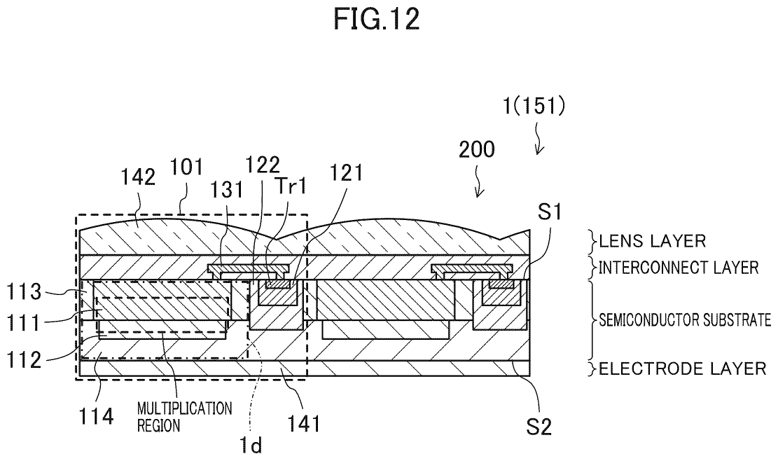

FIG. 12 is a cross-sectional view illustrating an example of a device structure of the photodetector shown in FIG. 8. FIG. 12 shows a cross section taken along line A-A′ shown in FIG. 11.

As shown in FIG. 12, the interconnect layer is formed on the first principal surface S1 of the semiconductor substrate, and an electrode layer including an electrode 141 is formed on a second principal surface S2 of the semiconductor substrate. A lens layer including a lens 142 is formed above the interconnect layer in the drawing.

First to fourth semiconductor layers 111 to 114, a first well 121, a second well 122, and the first transistors Tr1 are formed in the semiconductor substrate. Although not illustrated, the second to sixth transistors Tr2 to Tr6 are also formed in the semiconductor substrate.

The first semiconductor layer 111 of a first conductivity type and the third semiconductor layer 113 of the first conductivity type surrounding the first semiconductor layer 111 are formed in a portion of the semiconductor substrate near the first principal surface S1. The first well 121 and the second well 122 surrounding the first well 121 are formed on the right side of the third semiconductor layer 113 in the drawing. The first well 121 surrounds the first to sixth transistors Tr1 to Tr6.

The second semiconductor layer 112 of a second conductivity type that is different from the first conductivity type and the fourth semiconductor layer 114 of the second conductivity type surrounding the second semiconductor layer 112 are formed in a portion of the semiconductor substrate near the second principal surface S2.

The first to fourth semiconductor layers 111 to 114 constitute the SPAD 1d. The first and second semiconductor layers 111 and 112 form a multiplication region of the SPAD 1d. In FIG. 12, a photon is incident on the SPAD 1d from near the first principal surface S1. A voltage is applied through the electrode 141 to each of the anode of the SPAD 1d and the second semiconductor layer 112.

Here, the second resistor R2 does not have to be mounted on the semiconductor substrate, and may be configured as a diffusive resistance of the semiconductor substrate, the junction between the semiconductor substrate and the electrode, a resistance of the electrode, or any other element. For example, lowering the impurity concentration in the semiconductor substrate and increasing the thickness of the semiconductor substrate can satisfy the formula (1). This leads to elimination of providing a second resistor R2 in addition to the semiconductor chip or a film connected to the semiconductor chip, and can reduce components outside the semiconductor chip.

At least one portion of a region of the third semiconductor layer 113 tangent to the first principal surface S1 may be depleted. The third semiconductor layer 113 functions to separate the first semiconductor layers 111 adjacent to each other, and to separate the first semiconductor layers 111 and the first well 121. This can reduce the distance between the first semiconductor layers 111 adjacent to each other or the distance between the first semiconductor layers 111 and the first well 121, and can further miniaturize the photodetector 1.

A region where the third semiconductor layer 113 is arranged and which is tangent to the first principal surface S1 do not have to include a contact or a trench. This can reduce defects and noise.

The potential barrier formed by the depletion of the third semiconducting layer 113 may be larger than the change in the voltage of the cathode of the SPAD 1d (i.e., the first semiconductor layer 111) caused by the avalanche multiplication. This can substantially prevent the charge overflow between the SPADs 1d adjacent to each other or between the SPAD 1d and the first well 121 adjacent to each other.

In FIG. 12, the first to fourth semiconductor layers 111 to 114 are represented as different semiconductor layers for convenience's sake. However, these semiconductor layers do not always have to be formed at different impurity concentrations, through implantation of different impurities, or under any other similar conditions, and may have the same impurity concentration, for example.

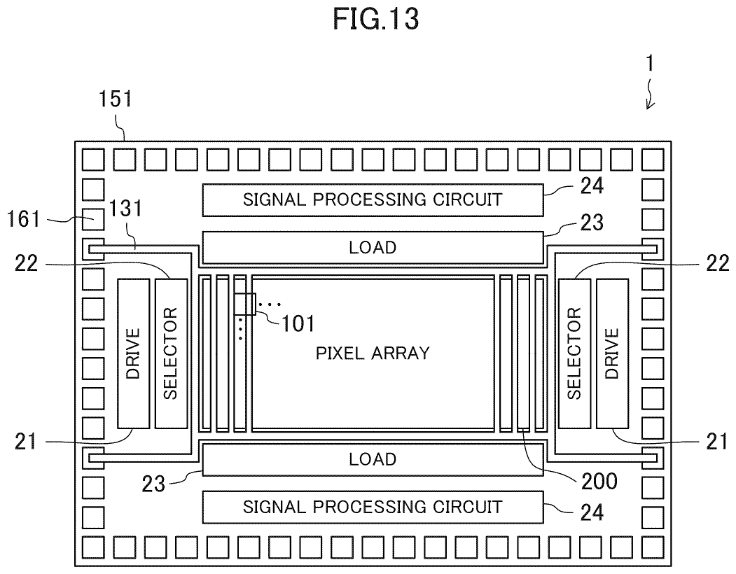

FIG. 13 is a plan view illustrating an example of the device structure of the photodetector shown in FIG. 8. FIG. 13 schematically shows the layout of the third interconnect 133.

As shown in FIG. 13, the pixel array 200 including the plurality of pixels 101, the drive 21, the selector 22, the load 23, and the signal processing circuit 24 are arranged on the semiconductor chip 151. A plurality of pads 161 are arranged on, and along the periphery of, the semiconductor chip 151 to surround the pixel array 200. The plurality of pads 161 include, for example, pads 161 which are connected to the external first to fourth power supplies Va to Vd to supply electric power to the pixels 101. As illustrated in FIG. 13, the third interconnect 133 is connected to some of the pads 161. The pads 161 connected to the third interconnect 133 are connected to the first power supply Va, and receive electric power supplied from the first power supply Va. This can reduce the resistance value R₁ of the first resistor R1. The third interconnect 133 that is thicker than the interconnects in the semiconductor chip 151 can also reduce the resistance value R₁ of the first resistor R1. This makes it easier to satisfy the conditions of the formula (1).

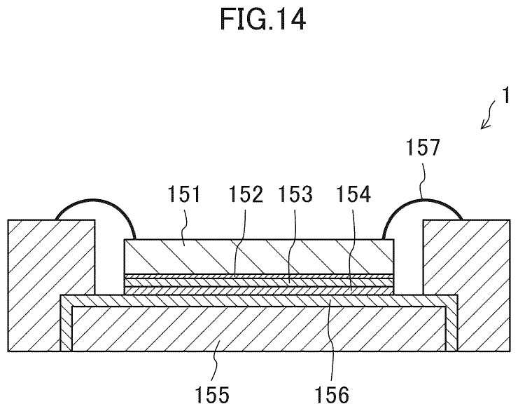

FIG. 14 is a cross-sectional view illustrating an example of the device structure of the photodetector shown in FIG. 8. As illustrated in FIG. 14, an adhesive layer 154, a resistance layer 153, a contact layer 152, and a semiconductor chip 151 are stacked above a package 155 and a base 156. In FIG. 14, the resistance layer 153 corresponds to the second resistor R2. Thus, the second resistor R2 with a small area can be arranged outside the semiconductor chip 151. Electric power is supplied from the outside to the semiconductor chip 151 via the outside through wires 157.

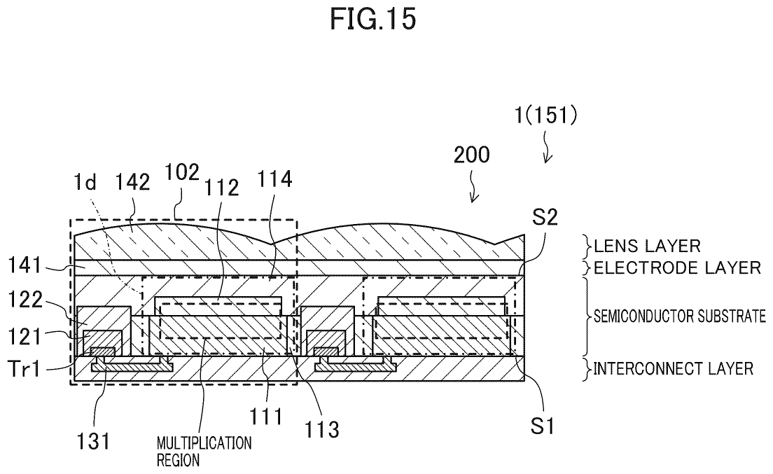

FIG. 15 is a cross-sectional view illustrating another example of the device structure of the photodetector shown in FIG. 8. In FIG. 15, a lens layer is formed near an electrode layer unlike in FIG. 11. That is, in FIG. 15, a photon is incident on the SPAD 1d from a surface of the associated pixel 102 near the second principal surface S2. In this case, a material with a high optical transmittance is used for the electrode 141. For example, if the wavelength range to be used is the visible to near-infrared range, indium tin oxide (ITO) or any other similar material is used.

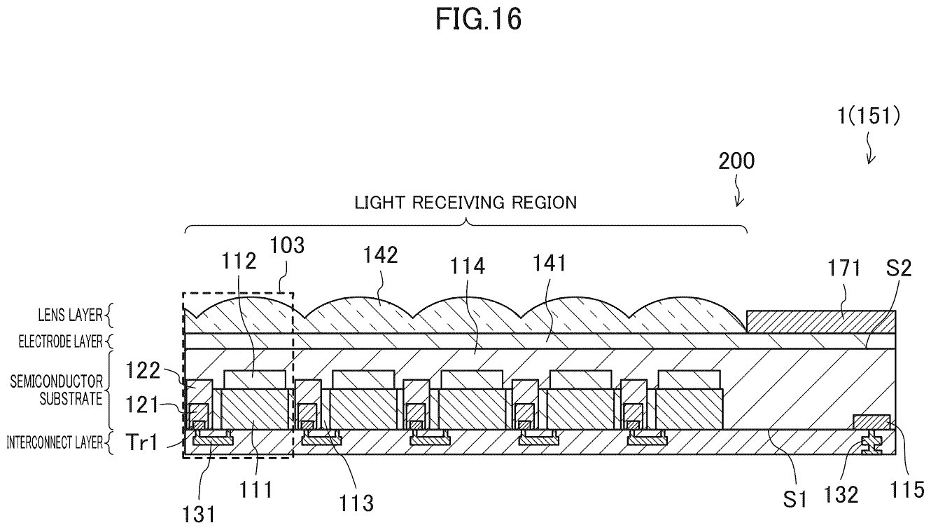

FIG. 16 is a cross-sectional view illustrating still another example of the device structure of the photodetector shown in FIG. 8. In FIG. 16, the second interconnect 132 and a fifth semiconductor layer 115 are arranged outside a light receiving region of the semiconductor chip 151 unlike in FIG. 15. In FIG. 16, five pixels 103 are arranged side by side in the lateral direction of the drawing.

In FIG. 16, the voltage of the second power supply Vb is applied to the anode (the second semiconductor layer 112) of the SPAD 1d via the second interconnect 132, the fifth semiconductor layer 115, the fourth semiconductor layer 114, and the electrode 141. In this case, the main component of the second resistor R2 may be the interconnect resistance of the second interconnect 132 or a resistor connected to the second interconnect 132. Thus, the second resistor R2 can be provided in the interconnect layer or in the semiconductor substrate. Examples of the resistor connected to the second resistor R2 include an interconnect resistance, a contact resistance, and a diffusive resistance. In particular, the associated interconnect may be made of a high-resistance material such as polysilicon or aluminum oxide.

Note that the electrode 141 does not always have to be provided. This can substantially prevent a decrease in light sensitivity resulting from light reflection and absorption of the electrode, and can improve the sensitivity.

The resistance values of the fourth semiconductor layer 114 and the fifth semiconductor layer 115 may be lower than the resistance values of the second resistor R2 and the resistor connected to the second interconnect 132. Lowering the resistance value of the fourth semiconductor layer 114 can substantially prevent the voltage of the fourth semiconductor layer 114 within the semiconductor substrate from being nonuniform.

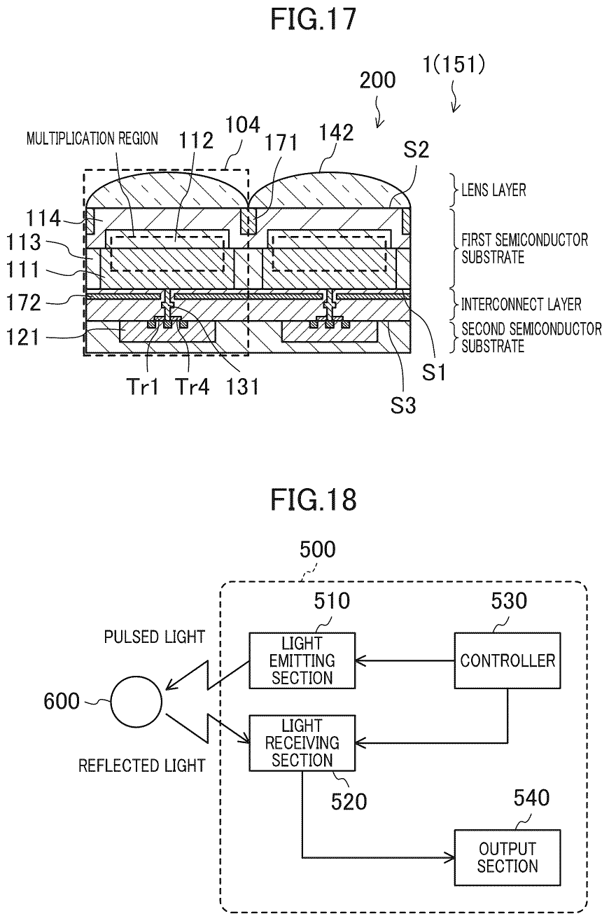

FIG. 17 is a cross-sectional view illustrating yet another example of the device structure of the photodetector shown in FIG. 8. In FIG. 17, the semiconductor chip 151 includes a first semiconductor substrate, a second semiconductor substrate, a lens layer, and an interconnect layer, and a plurality of pixels 104 are formed in the semiconductor chip 151.

Specifically, a lens layer is formed on the second principal surface S2 of the first semiconductor substrate. The interconnect layer is formed between the first principal surface S1 of the first semiconductor substrate and a third principal surface S3 of the second semiconductor substrate.

The first semiconductor substrate includes first to fourth semiconductor layers 111 to 114 which constitute an SPAD 1d. A trench 171 extending in the top-to-bottom direction of the drawing is formed between the second semiconductor layers 112 adjacent to each other.

Although not illustrated, the trench 171 is formed in the form of a lattice in plan view to separate the second semiconductor layers 112 of the pixels 104 from one another. The trench 171 made of a material that reflects incident light can reduce crosstalk between the pixels 104 adjacent to each other.

A first well 121, the first transistor Tr1, and the fourth transistor Tr4 are formed on the second semiconductor substrate. The first and fourth transistors Tr1 and Tr4 are connected to the first semiconductor layer 111 via the first interconnect 131 formed in the interconnect layer. Although not illustrated, the transistors in FIG. 8 are formed on the second semiconductor substrate.

A reflector 172 is formed in the interconnect layer. The reflector 172 is made of a material that reflects incident light. This makes it easier to allow incident light incident on the pixels 104 to enter the associated SPADs 1d.

In FIG. 17, the SPADs 1d are formed in the first semiconductor substrate, and the second semiconductor substrate and the interconnect layer include a circuit including transistors and interconnects. Thus, the SPADs 1d and circuit sections can be separately fabricated. Transistors and interconnects are formed in another substrate (a second semiconductor substrate). This can increase the aperture ratio of each SPAD 1d, and can improve the light use efficiency.

FIG. 18 is a block diagram illustrating a distance measuring system according to a fifth embodiment. A distance measuring system 500 includes a light receiving section 520 that include the photodetector, a light emitting section 510 that emits light toward a measurement target 600, a controller 530 that controls the light receiving section 520 and the light emitting section 510, and an output section 540 that receives a signal corresponding to reflected light reflecting off the measurement target 600 from the light receiving section 520 and calculates the distance to the measurement target 600.

The distance measuring system 500 including the photodetector with increased sensitivity can avoid false distance detection, and can determine the distance to the measurement target 600 with high accuracy.

In the foregoing description, the embodiment serves as an example of the technique disclosed in the present application. However, the technique in the present disclosure is not limited to the embodiment, and is also applicable to embodiments where modifications, substitutions, additions, or omissions are made appropriately.

In FIGS. 11 to 18, a case where the photodetector in FIG. 8 is formed in the semiconductor chip 151 has been described as an example. However, this is merely an example. The photodetector in any one of FIGS. 1, 4, and 6 may be formed in the semiconductor chip 151 just like in FIG. 8.

What is claimed is:

1. A photodetector comprising:
a plurality of pixels,
each of the pixels including:
a single photon avalanche diode (SPAD); and
a first element being a variable resistor or a switch, and having an end in one direction connected to one end of the SPAD,
ends of the first elements in another direction being connected together in parallel,
other ends of the SPADs being connected together in parallel, the other ends connected together in parallel being connected to a second resistor,
a resistance value of the second resistor being higher than a resistance value of a resistive component at the end of each of the first elements in the another direction.

2. The photodetector of claim 1, wherein
the first element is conductive during a reset period, and is non-conductive during a light exposure period.

3. The photodetector of claim 2, wherein
the second resistor quenches avalanche multiplication during the reset period.

4. The photodetector of claim 3, wherein
the second resistor has a resistance value higher than or equal to 100Ω.

5. The photodetector of claim 3, wherein
the number of the pixels is 10,000 or more.

6. The photodetector of claim 1, wherein
the first element is a first reset transistor.

7. The photodetector of claim 6, wherein
a conductivity type of the first reset transistor is identical to that of an end of the first reset transistor in one direction, the end being connected to an associated one of the SPADs.

8. The photodetector of claim 7, wherein
the other ends of the SPADs connected together in parallel are connected to a first capacitor in parallel with the second resistor, and
an RC time constant caused by the second resistor and the first capacitor is greater than a duration of the reset period.

9. The photodetector of claim 1, wherein
each of the pixels further includes:
a floating diffusion;
a transfer transistor configured to transfer charges stored in the SPAD to the floating diffusion;
a second reset transistor configured to reset the floating diffusion;
a source follower transistor that is a portion of a source follower circuit configured to read a voltage of the floating diffusion, and has a gate connected to the floating diffusion; and
a selection transistor configured to deliver an output signal of a selected one of the pixels to a signal output line.

10. The photodetector of claim 9, wherein
each of the pixels further includes:
a storage transistor having a first end connected to the floating diffusion; and
a storage capacitor connected to a second end of the storage transistor, the second end being different from the first end.

11. The photodetector of claim 1, wherein
the pixels are arranged in an array on a semiconductor substrate,
a semiconductor layer is formed between the SPADs adjacent to each other in plan view, and
a trench or a contact is not formed on a first principal surface of a portion of the semiconductor substrate between the SPADs adjacent to each other.

12. The photodetector of claim 1, wherein
the pixels are arranged in an array,
the resistive component is an interconnect resistance, and
an interconnect that connects the first elements together is connected to a plurality of pads arranged to surround a periphery of the pixels.

13. The photodetector of claim 1, wherein
the pixels are arranged in an array on a semiconductor substrate,
the second resistor is arranged near a second principal surface of the semiconductor substrate,
the semiconductor substrate is arranged on a package, and
a voltage is applied to the second resistor via a base for the package.

14. The photodetector of claim 13, wherein
the second resistor is arranged outside the semiconductor substrate.

15. The photodetector of claim 14, wherein
the second resistor is configured as a resistance layer arranged between the semiconductor substrate and the base.

16. The photodetector of claim 14, wherein
the second resistor is provided on a mounting substrate on which the package is mounted.

17. The photodetector of claim 1, wherein
the pixels are arranged in an array on a semiconductor substrate, and
the second resistor is arranged near a first principal surface of the semiconductor substrate.

18. The photodetector of claim 17, wherein
a light-irradiated surface is closer to a second principal surface of the semiconductor substrate.

19. The photodetector of claim 18, wherein
the semiconductor substrate includes a first semiconductor substrate and a second semiconductor substrate different from the first semiconductor substrate,
the SPADs are arranged in the first semiconductor substrate, and
the transistors are arranged in the second semiconductor substrate.

20. A distance measuring system comprising:
a light receiving section including the photodetector of claim 1;
a light emitting section configured to emit light toward a measurement target; and
an arithmetic section configured to receive a signal corresponding to reflected light reflecting off the measurement target from the light receiving section, and to calculate a distance to the measurement target.
